(19) United States
(12) Patent Application Publication
(10) Pub. No.: US 2011/0250520 A1
(43) Pub. Date: Oct. 13, 2011

(54) VARIABLE LOAD FUEL CELL

(75) Inventors: Benjamin Lunt, Tewksbury, MA (US); Scott Blanchet, Chelmsford, MA (US)

(73) Assignee: Nuvera Fuel Cells, Inc.

(21) Appl. No.: 13/076,768

(22) Filed: Mar. 31, 2011

Related U.S. Application Data
(60) Provisional application No. 61/319,522, filed on Mar. 31, 2010.

(51) Int. Cl. H01M 8/24; G01R 19/00

(52) U.S. Cl. 429/468; 324/76.11

(57) ABSTRACT

Described herein are embodiments directed to fixtures for mounting fuel cells, the fixtures comprising at least one internal frame member; a first endplate assembly comprising a first seal frame, and a first active area compression plate, and a second endplate assembly; wherein the internal frame member is located between the first endplate assembly and the second endplate assembly. Also described are methods of testing a fuel cell.

This application claims the benefit of priority to U.S. Provisional Application No. 61/319,522 filed on Mar. 31, 2010, which is incorporated in its entirety herein.

The present disclosure is generally related to a fixture for testing fuel cells, or for mounting a fuel cell stack.

A typical polymer electrolyte membrane (“PEM”) fuel cell comprises an electrochemical package (ECP), which comprises a polymer membrane that serves as an electrolyte, an anode on one side of the polymer membrane, and a cathode on the other side of the membrane. The anode comprises an anode electrode catalyst. The reactant from the fuel gas, e.g., hydrogen, comes into contact with the anode electrode catalyst and may dissociate to produce protons. The polymer membrane, when adequately hydrated, allows protons to migrate across the membrane from the anode to the cathode. The cathode comprises a cathode electrode catalyst. The reactant from the cathode gas, e.g., oxygen, may form activated oxygen species on the cathode electrode catalyst, which react with the protons to form water. Such single fuel cells can be connected electrically in series to form a “fuel cell stack.”

The present disclosure provides a fixture suitable for testing fuel cells in order to determine how they will perform in a fuel cell stack. The fixture is also suitable for mounting a fuel cell stack. The fixture comprises at least one internal frame member, a first endplate assembly and a second endplate assembly. The fixture is adapted to house additional components, such as a first bipolar plate, a second bipolar plate, and an electrochemical package comprising a cathode, an anode, and a polymer membrane interposed between the cathode and the anode.

In certain embodiments, the fixture comprises a first endplate assembly; a second endplate assembly; at least one internal frame member mounted between the first endplate assembly and the second endplate assembly; and a segmented current collector comprising a multiplicity of current collecting segments, wherein the current flowing through one current collecting segment can be measured independently of the current flowing through other current collecting segments.

In certain embodiments each current collecting segment is substantially insulated from the other current collecting segments.

In other embodiments, the fixture comprises at least one internal frame member; a first endplate assembly comprising a first seal frame, and a first active area compression plate and a second endplate assembly; wherein the internal frame members are located between the first endplate assembly and the second endplate assembly; a first compressive force may be applied between the first seal frame and the second endplate assembly; a second compressive force may be applied between the first active area compression plate and the second endplate assembly; and the second compressive force is applied independent from application of the first compressive force. Thus, one aspect of the disclosure is a multi-part endplate assembly

In certain embodiments, the second endplate assembly comprises a second seal frame and a second active area compression plate; wherein the first compressive force may be applied between the first seal frame and the second seal frame and the second compressive force may be applied between the first active area compression plate and the second active area compression plate.

In certain embodiments, the frame is adapted to allow the mounting of interchangeable flowfield elements. In other embodiments, an interchangeable flowfield element is mounted to the frame.

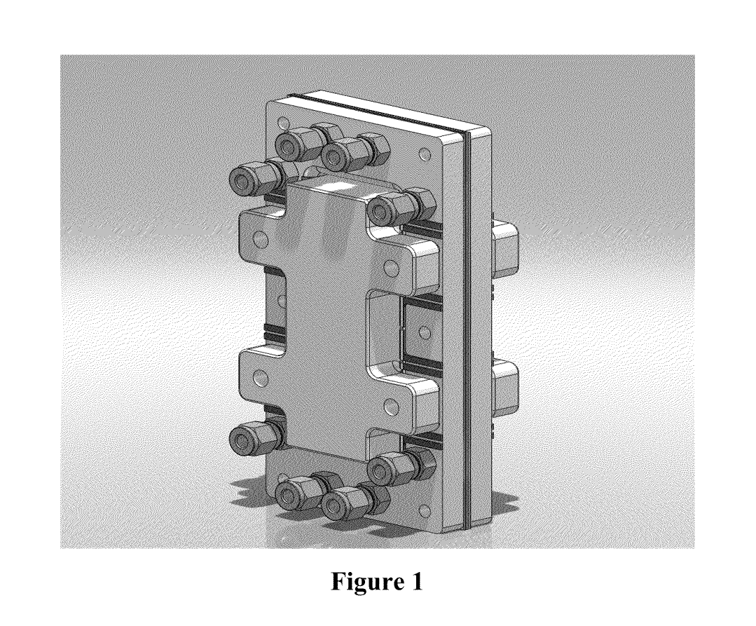

FIG. 1 illustrates a frame located between two endplate assemblies, wherein the endplate assembly comprises a seal frame and an active area compression plate.

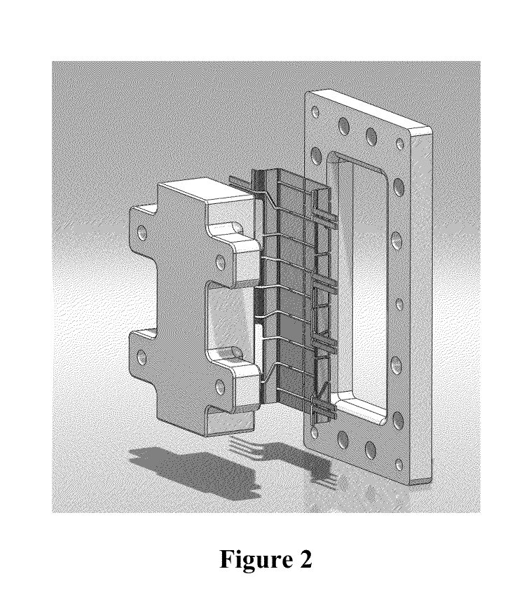

FIG. 2 provides an exploded view of an endplate assembly comprising a seal frame, an active area compression plate; and a segmented current collector

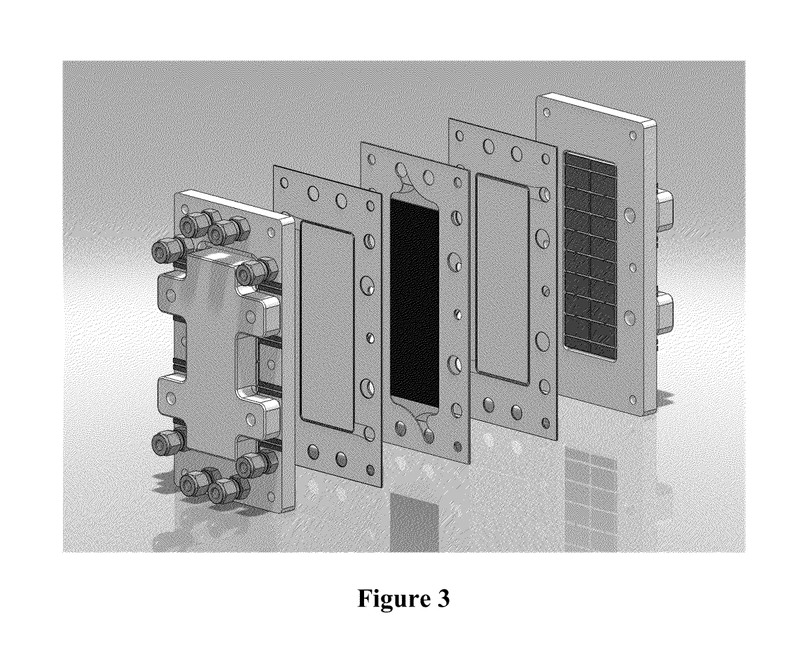

FIG. 3 illustrates an embodiment of the invention, comprising two endplate assemblies, a frame, and two cooling cells.

As disclosed herein, a fuel cell fixture comprises two endplate assemblies, and a frame. The fixture may also comprise a current collector and/or interchangeable flowfield elements, and/or cooling cells. The fixture is adapted to house additional components such as one or more electrochemical packages and one or more bipolar plates. When the fixture is assembled with these additional components, one or more fuel cells are formed that are sandwiched between the two endplates of the fixture. When a fuel cell is assembled in the fixture, the electrochemical package is located between two bipolar plates. In certain embodiments, the fixture is adapted to test the performance of those fuel cells under a wide range of operating conditions. In other embodiments, the fixture is adapted to mount a fuel cell stack.

As disclosed herein, an electrochemical package (“ECP”) refers to a component comprising a polymer membrane that serves as an electrolyte, an anode on one side of the polymer membrane, and a cathode on the other side of the membrane. The ECP may also comprise other layers known to those of skill in the art, for example, a gas diffusion layer, anode catalyst, and cathode catalyst. An electrode refers to the anode or the cathode.

As used herein, the anode is exposed to a fuel gas (i.e., the anode gas) in a fuel cell. The reactant from the fuel gas, e.g., hydrogen, may experience catalytic reactions when coming into contact with the anode catalyst.

As used herein, the cathode is exposed to an oxidant gas (i.e., the cathode gas). The reactant from the cathode gas, e.g., oxygen, may experience catalytic reaction when coming into contact with the cathode catalyst.

As used herein, a fuel cell component is in direct contact with an electrode of the ECP if it can be in direct contact with the catalyst, in direct contact with the catalyst layer, or in direct contact with the gas diffusion layer. As used herein, the geometric area of an anode or a cathode refers to the projected, planar area of the portion of the polymer membrane that is covered by or otherwise in direct contact with an electrode catalyst, commonly referred to by those in the fuel cell industry as the active area of the anode or cathode.

As used herein, a separator plate, also known as a bipolar plate, refers to an electrically conductive gas barrier. The bipolar plate can be comprised of, for example, graphite or metal. The anode compartment refers to the space between a first bipolar plate and the anode, while the cathode compartment refers to the space between a second bipolar plate and the cathode. As used herein, a fuel cell compartment refers to either an anode compartment or a cathode compartment.

A fuel cell compartment can be enclosed at its periphery in the planar direction by a gas seal. The gas seal has openings that serve as gas inlets or outlets for the fuel cell compartment. The inlets and outlets of the compartment are fluidly connected to gas manifolds, which are fluid conduits connecting the inlets and a gas source, or connecting the outlets and a gas exit point. An example of a gas seal is the frame of the fixture disclosed herein.

As disclosed herein, the endplates of the fixture allow for the application of compressive forces that may hold the fixture together when assembling a fuel cell or fuel cell stack in the fixture. For example, one or more compressive forces may be applied between the two endplates, thereby sealing the fixture assembly to ensure the fuel and oxidant reagents do not leak out of the fuel cell or fuel cell stack assembled in the fixture. Where multiple compressive forces are applied between the two endplates, those forces may be the same, or different. A compressive force may be applied between the endplates, for example, using one or more tie rods passing through the perimetrical region of the fixture.

In some embodiments, one or both endplates may be a multi-part assembly, comprising a seal frame, which forms the perimetrical portion of the endplate assembly, and an active area compression plate, which forms the central portion of the endplate. The seal frame has a void space corresponding essentially to the active area of a fuel cell or fuel cell stack assembled in the fixture. At least one portion of the active area compression plate overlaps the perimetric region of the seal frame on its external side. One portion of the active area compression plate is adapted to occupy the void space of the seal frame corresponding to the active area of a fuel cell assembled in the fixture.

Where one or both of the endplates are multi-part assemblies, a first compressive force may be applied between the seal frame and the opposing endplate, and a second compressive force may be applied between the active area compression plate and the opposing endplate. The force applied between the active area compression plate and opposing endplate may be different from the force applied between the seal frame and the opposing endplate. This allows the pressure applied by the active area compression plate to be adjusted independent of the pressure applied by the seal frame.

Where both of the endplates are multi-part assemblies, a first compressive force may be applied between the seal frame of one endplate and the seal frame of the second endplate, and a second compressive force may be applied between the active area compression plate of one endplate and the active area compression plate of the second endplate. The first and second compressive forces may be the same, or different. This allows the pressure applied by the active area compression plates to be adjusted independent of the pressure applied by the seal frames.

The pressure applied by a seal frame may be any value allowing for an effectively sealed fuel cell or fuel cell stack assembly. The pressure must be high enough to effectively seal the fixture, but not so high that components of the fixture, or fuel cell assembled therein, are deformed, thus compromising the seal. Accordingly, the maximum pressure that may be applied by the seal frame will depend on the materials used in constructing the frame of the fixture and the seal components of the fuel cell assembled in the fixture. For example, the pressure applied by a seal frame may range from 5 to 50 kilograms per square centimeter, or alternatively, the pressure applied by a seal frame may range from 5 to 15 kilograms per square centimeter

Similarly, the pressure applied by an active area compression plate may be any value allowing for operation of a fuel cell assembled in the fixture. In particular, a minimum pressure must be applied by the active area compression plate to ensure the integrity of the fuel cell assembled in the fixture. This minimum pressure can be, for example, less than 10 kilograms per square centimeter. The pressure applied by an active area compression plate must not be so great as to lead to the mechanical failure of an assembled fuel cell. Thus, the maximum pressure that may be applied by an active area compression plate will depend on the architecture of a fuel cell assembled in the fixture, and the materials from which that fuel cell are made. The pressure applied by an active area compression plate may range, for example, from 9 kilograms per square centimeter to 48 kilograms per square centimeter, including pressures ranging from 10 kilograms per square centimeter to 40 kilograms per square centimeter, 12 kilograms per square centimeter to 36 kilograms per square centimeter, and 15 kilograms per square centimeter to 30 kilograms per square centimeter . Alternatively, the pressure applied by an active area compression plate may range from 20 kilograms per square centimeter to 40 kilograms per square centimeter.

Each endplate has a perimeter area that may be adapted to allow the inlet and/or outlet of reactant gases, temperature control fluid, exhaust, and other inputs required by the fuel cell assembled in the fixture. For example, one endplate may have a nozzle to allow inlet of oxidant gas into a portion of the fixture, a separate nozzle to allow inlet of fuel gas into a separate portion of the fixture, and a third nozzle to allow inlet of coolant into a portion of the fixture.

As disclosed herein, the frame is a structural element of the fixture adapted to prevent the leakage of fuel and oxidant gases from an assembled fuel cell, when located between the two endplates in the assembled fixture. The frame corresponds to the perimetrical region of the endplates, and has a void space corresponding essentially to the active area of fuel cells to be assembled in the fixture. The frame may have one or more openings allowing for the passage of tie rods. The frame may have one or more openings in correspondence with a nozzle on the endplate for the passage of oxidant gas. These openings may be connected to an inlet channel in a face of the frame, which allows the passage of oxidant gas into the cathode compartment of a fuel cell assembled in the fixture.

The frame may also have one or more openings in correspondence with a nozzle on the endplate for the passage of fuel gas. These opening may be connected to an inlet channel in a face of the frame, which allows the passage of fuel gas into the anode compartment of a fuel cell assembled in the fixture.

The frame may also have one or more openings for the passage of reaction products. These openings may be connected to one or more outlet channels in the face of the frame, allowing the passage of reaction products and unreacted gas out of the fuel cell compartments. Finally, the frame may also have one or more openings in correspondence with the appropriate nozzle on the endplate for the passage of coolant.

Moreover, the frame may be adapted to mount components of the fuel cell assembled in the fixture. For example, the frame may be adapted so that the ECP may be mounted on the frame. The frame also may be adapted to allow the mounting of interchangeable flowfield elements for each fuel cell compartment on the frame.

As used herein, a flowfield is a structural element disposed between an ECP and a bipolar plate in a planar orientation in parallel with the bipolar plate, which allows gas to flow through and is enclosed at its periphery by the frame having inlets and outlets from one or more gas manifolds. Without structural support, a fuel cell compartment may collapse under pressure during the assembly of the fuel cell in the fixture, making a significant portion of the electrode inaccessible to the reactant gas. A flowfield should thus have a certain degree of structural integrity so that it does not completely collapse under pressure.

A flowfield should also facilitate the even distribution of the reactant gas to the electrode. The contacting area between the flowfield and the electrode should be small so that most area of the electrode is accessible to the reactant gas but still maintain good electrical conductivity. Furthermore, it is desirable that the flowfield does not create excessive pressure drop in the reactant gas flow.

An open flowfield refers to a structure in which any point within flowfield may belong to several fluid pathways, i.e., multiple fluid pathways intersect at that point. For example, in an open flowfield, a fluid can follow two or more pathways from any point within the flowfield to an outlet. In contrast, in a flowfield that has discrete channels linking an inlet and an outlet, the fluid in one channel may only follow one pathway, defined by that channel, to the outlet.

One material suitable as an open flowfield is a porous foam. A piece of foam has a reticulated structure with an interconnected network of ligaments and interconnected voids within the geometric boundary defined by the contour of the metal foam. Because of this unique structure, the foam material in an uncompressed state can have a porosity that reaches greater than 50%, such as, for example, greater than 60%, greater than 70%, greater than 75%, greater than 80%, greater than 85%, greater than 90%, greater than 95%, and greater than 98%.

The network of interconnected voids form pathways that extend throughout the foam. Accordingly, a fluid entering the porous structure at one point on its geometric boundary may follow several different pathways to reach a location inside or at another boundary of the foam. The foam may be made of metal or graphite. For example, metal foams are commercially available from Porvair Advanced Materials, Inc. Graphite foams are also commercially available, for example, from Poco Graphite, Inc., Decatur, Tex.

Another example of porous structures suitable as an open flowfield include expanded metal mesh. An expanded metal mesh is made from sheets of solid metal that are uniformly slit and stretched to create openings of certain geometric shapes, e.g., a diamond shape. In a standard expanded metal, each row of diamond-shaped openings is offset from the next, creating an uneven structure. The standard expanded metal sheet can be rolled to produce a flattened expanded metal. A metal wire mesh is also a porous structure suitable as an open flowfield. It can be made by weaving or welding metal wires together. Both metal wire mesh and expanded metal mesh are commercially available, for example, from Mechanical Metals, Inc. of Newtown, Pa. When used as an open flowfield, the expanded metal mesh and the metal wire mesh may first be processed to form a non-flat geometric shape.

A further example of a porous structure suitable as an open flowfield is a formed metal sheet with perforations. As used herein, a formed metal sheet refers to a metal sheet that has a non-flat geometric shape. It may have a raised or embossed surface. It may be a corrugated metal sheet with undulating ridges and grooves. It may also have discontinuous indentations and protrusions.

Once provided with a sufficient number of perforations, a formed metal sheet may be used as an open flowfield, allowing fluids to flow in the fuel cell compartment with little restriction. Such a perforated metal sheet may have repeated arrays of perforations, e.g., round holes, hexagonal holes, square holes, slotted hole, etc. It can be stamped to form undulating ridges and grooves, or indentations and protrusions, or other geometric shapes. An example of perforated metal sheets that are commercially available can be obtained from McNichols Co., Tampa, Fla.

A formed metal sheet without perforations may also serve as an open flowfield. One example is a formed metal sheet having arrays of protrusions. The tips of the protrusions contact the ECP, creating a continuous void space between the ECP and the rest of the metal sheet. As a result, a fluid can travel from one point in the continuous void to another through multiple pathways.

A formed metal sheet may be made by a sheet metal forming process such as stamping. It may also form channels by removing part of the surface material, such as by etching and laser engraving, so that the thickness of the metal sheet varies. Enclosed channels may form between the raised surface of a formed metal sheet with an adjacent flat surface, such as an ECP.

In contrast to open flowfields, some non-open flowfields contain a plurality of discrete flow pathways that are physically separated and distinct from one another. An example of the latter is a graphite sheet having discrete channels molded on its surface. Each channel connects an inlet with an outlet of the fuel cell compartment. In such a case, the ridges and valleys of the channels create a space between the bulk structure of the bipolar plate and the ECP, forming an enclosed pathway for the fluid to pass through. In this structure, aside from gas diffusion into the ECP, the bulk of the gas fluid flows within the channel from inlet to the outlet. The arrangement of channels may vary, for example, a channel may split into multiple channels and multiple channels may merge into one, therefore creating locations in the flowfield where multiple channels intersect. However, the number of such locations are finite, and in the majority of the flowfield the gas fluid has only one pathway, which is defined by the section of channel where the gas fluid resides.

Thus, by incorporating interchangeable flowfield elements into the fixture, the fixture may be used to test or operate a single ECP under various flowfield conditions in the same mounting fixture.

The fixture may also comprise one or more current collectors. Each current collector is adapted so as to be in electrical communication with one of the electrodes when a fuel cell is assembled in the fixture. In certain embodiments, the current collector provides a means of measuring the current output of a fuel cell being tested in the fixture. When a fuel cell is assembled in the fixture, the planar projection of the current collector substantially corresponds to the electrode with which it is in electrical communication. The current output of the current collector provides a means of assessing the efficiency of a fuel cell mounted in the fixture.

In certain embodiments of the invention, one or more of the current collectors is a segmented current collector. As used herein, a segmented current collector is a current collector comprising a multiplicity of current collecting segments, each of which, when a fuel cell is assembled in the fixture, is in electrical communication with a portion of an electrode. Each current collecting segment is substantially insulated from the other current collecting segments. Thus, the current flowing through each current collecting segment may be measured independently of the current flowing through the other current collecting segments.

Accordingly, each current collecting segment may be used to assess the current output of a specific portion of an electrode in a fuel cell mounted in the fixture. This is because, when a fuel cell is mounted in the fixture, a substantial portion of the current flowing through a current collecting segment results from the reaction of fuel or oxidant gas at the portion of the electrode corresponding to the planar projection of that current collecting segment. Thus, the segmented current collector allows the user to assess the efficiency of reaction at a specific portion of the electrode in the fuel cell mounted in the fixture.

As used herein, current spread refers to any current flowing through a current collecting segment when a fuel cell is assembled in the fixture that results from a path of least resistance between the electrode and a current collecting segment that does not correspond to the planar projection of that current collecting segment. Thus, current spread is current that is not associated with a chemical reaction taking place at the portion of the electrode corresponding to the planar projection of the current collecting segment.

The amount of current spread measured by a segmented electrode can be determined in a separate apparatus. This determined current spread can then be used to adjust the measured current in an assembled fuel cell by a current collecting segment. This can be done by subtracting the typical current spread determined in the external apparatus from the actual current measured in the operating fuel cell by that current collecting segment. The calculated current with then substantially correspond reflect the current produced by chemical reactions taking place at the portion of the electrode corresponding to the planar projection of the current collecting segment.

One aspect of the fixture disclosed herein is its ability to test a fuel cell under conditions mimicking those under which the fuel cell will operate when assembled into a complete fuel cell stack. For example, by incorporating interchangeable flowfield elements, the pathway from gas inlet to gas outlet can be made the same in the test fixture as it will be in an assembled stack. Thus, the temperature and pressure gradients within the fixture will mimic those of the assembled stack, and allow for more meaningful test results.

Additionally, one or more cooling cells, such as, for example, those disclosed in U.S. patent application Ser. No. 10/524,040, may be incorporated into the fixture. in order to provide an accurate temperature environment in which to test the fuel cells. In particular, where two or more cooling cells are incorporated, each cooling cell may be supplied by its own coolant source, thus allowing independent control of the temperature of multiple environments within the test fixture. For example, one cooling cell may be placed next to the anode compartment and a separate, independently fed, cooling cell may be placed next to the cathode compartment, allowing independent temperature control of each compartment.

The fixture disclosed herein also allows a new fuel cell operating method, applicable to both single cells as well as fuel cell stacks. The compressive state of the cell or stack can be adjusted according to the fuel cell or stack operating state in order to achieve a desired performance target or setpoint.

For example, it is common that after several thermal (on/off) cycles, the components of the cell or stack undergo a certain relaxation in response to induced mechanical stresses that has a net result of increasing the electrical resistance of the cell or stack assembly thereby diminishing performance. The electrical resistance of the cell or stack assembly may be modulated in the present fixture by adjusting the compressive pressure applied by an active area compression plate.

Thus, by using a voltage measurement (standard procedure in fuel cell operation) and detecting a deviation from an expected reference value, the pressure applied by an active area compression plate could be actively adjusted under a feedback control scheme to increase the performance of the fuel cell or stack. The adjustment made in this way could be automated. Other feedback signals could include high frequency resistance, current density distribution metrics, cell or stack dimensional measurements, among others.

It will be apparent to those skilled in the art that various modifications and variations can be made without departing from the spirit of the invention. The present invention covers all such modifications and variations, provided they come within the scope of the claims and their equivalents.

We claim:

1. A fixture for mounting fuel cells, the fixture comprising
at least one internal frame member;
a first endplate assembly comprising
a first seal frame, and
a first active area compression plate
and a second endplate assembly; wherein
the internal frame member is located between the first endplate assembly and the second endplate assembly.

2. The fixture according to claim 1, wherein
a first compressive force may be applied between the first seal frame and the second endplate assembly;
a second compressive force may be applied between the first active area compression plate and the second endplate assembly; and
the second compressive force is applied independent from application of the first compressive force.

3. The fixture according to claim 2, wherein
the second endplate assembly comprising a second seal frame and a second active area compression plate; and
the first compressive force may be applied between the first seal frame and the second seal frame and the second compressive force may be applied between the first active area compression plate and the second active area compression plate.

4. The fixture according to claim 3, wherein the compressive force applied between the first seal frame and the second seal frame results in an applied pressure ranging from 5 to 50 kilograms per square centimeter.

5. The fixture according to claim 4, wherein the compressive force applied between the first seal frame and the second seal frame results in an applied pressure ranging from about 5 to 15 kilograms per square centimeter

6. The fixture according to claim 3, wherein the compressive force applied between the first active area compression plate and the second active area compression plate results in an applied pressure ranging from 9 to 48 kilograms per centimeter.

7. The fixture according to claim 6, wherein the compressive force applied between the first active area compression plate and the second active area compression plate results in an applied pressure ranging from about 20 to 40 kilograms per centimeter.

8. The fixture according to claim 1 wherein the internal frame member is adapted to allow the mounting of interchangeable flowfield elements.

9. The fixture according to claim 8, wherein an interchangeable flowfield element is mounted on the internal frame member.

10. The fixture according to claim 1, further comprising at least one cooling cell.

11. A fixture for testing fuel cells, the fixture comprising
a first endplate assembly;
a second endplate assembly;
at least one internal frame member mounted between the first endplate assembly and the second endplate assembly;
and a segmented current collector comprising a multiplicity of current collecting segments, wherein the current flowing through one current collecting segment can be measured independently of the current flowing through other current collecting segments.

12. The fixture according to claim 11, wherein
a first compressive force may be applied between the first seal frame and the second endplate assembly;
a second compressive force may be applied between the first active area compression plate and the second endplate assembly; and
the second compressive force is applied independent from application of the first compressive force.

13. The fixture according to claim 11, wherein each current collecting segment is substantially insulated from the other current collecting segments.

14. The fixture according to claim 11, wherein the internal frame member is adapted to allow the mounting of interchangeable flowfield elements.

15. The fixture according to claim 14, wherein an interchangeable flowfield element is mounted on the internal frame member.

16. The fixture according to claim 11, further comprising at least one cooling cell.

17. A method of testing a fuel cell comprising assembling a fuel cell in a test fixture by housing an electrochemical package and two bipolar plates in the test fixture, and measuring a current output of the fuel cell; the fixture comprising at least one internal frame member; a first endplate assembly comprising a first seal frame, and a first active area compression plate; and a second endplate assembly; wherein the internal frame member, the electrochemical package and the two bipolar plates are located between the first endplate assembly and the second endplate assembly; a first compressive force may be applied between the first seal frame and the second endplate assembly; a second compressive force may be applied between the first active area compression plate and the second endplate assembly; and the second compressive force is applied independent from application of the first compressive force.

18. The method of claim 17, wherein the first compressive force results in a pressure applied by the seal frame ranging from 5 to 50 kilograms per square centimeter.

19. The method of claim 17, wherein the second compressive force results in a pressure applied by the first active area compression plate ranging from 9 to 48 kilograms per square centimeter.

20. The method of claim 17, wherein an interchangeable flowfield element is mounted to the internal frame member.
